(19) United States
(12) Patent Application Publication
(10) Pub. No.: US 2025/0393282 A1
(43) Pub. Date: Dec. 25, 2025

(54) SELF-ALIGNED BACKSIDE VBPR WITH WRAP AROUND CONTACT

(71) Applicant: International Business Machines Corporation, Armonk, NY (US)

(72) Inventors: GIDEON OYIBO, Rensselaer, NY (US); Tao Li, Slingerlands, NY (US); Ruilong Xie, Niskayuna, NY (US); Eric R Miller, Albany, NY (US)

(21) Appl. No.: 18/751,669

(22) Filed: Jun. 24, 2024

(51) Int. Cl. H01L 29/417; H01L 23/528; H01L 27/092; H01L 29/06; H01L 29/423; H01L 29/66; H01L 29/775; H01L 29/786

(52) U.S. Cl. CPC H10D 64/258; H01L 23/5286; H10D 30/014; H10D 30/43; H10D 30/6735; H10D 30/6757; H10D 62/121; H10D 64/021; H10D 84/85

(57) ABSTRACT

A microelectronic structure includes a nanosheet FET that includes a source/drain. A wrap around contact that is connected to the source/drain. The wrap around contact includes a horizontal section and a via section. The via section includes a protrusion that extends laterally into the source/drain.

### BACKGROUND

The present invention generally relates to the field of microelectronics, and more particularly to formation of wrap around source/drain contacts.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate components for each device without defects.

### BRIEF SUMMARY

Additional aspects and/or advantages will be set forth in part in the description which follows and, in part, will be apparent from the description, or may be learned by practice of the invention.

A microelectronic structure includes a nanosheet FET that includes a source/drain. A wrap around contact that is connected to the source/drain. The wrap around contact includes a horizontal section and a via section. The via section includes a protrusion that extends laterally into the source/drain.

A microelectronic structure a nanosheet FET that includes a source/drain. A horizontal spacer located on a backside surface of the source/drain. The source/drain extends past the end of the sidewall of the horizontal spacer. A vertical spacer located along a sidewall of the source/drain. A wrap around contact that is connected to the source/drain. The wrap around contact includes a horizontal section and a via section. The via section includes a protrusion that extends laterally into the source/drain.

A microelectronic structure a nanosheet FET that includes a source/drain. A horizontal spacer located on a backside surface of the source/drain. The source/drain extends past the end of the sidewall of the horizontal spacer. A vertical spacer located along a sidewall of the source/drain. A first side of the source/drain is in direct with the vertical spacer. A wrap around contact that is connected to the source/drain. The wrap around contact includes a horizontal section and a via section. The via section includes a protrusion that extends laterally into the source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross-section X of the nanosheet transistor after the formation of the dummy gate, hardmask, a first spacer, and a gate spacer, in accordance with the embodiment of the present invention.

FIG. 3 illustrates a cross-section Y of the source/drain region after the formation of the dummy gate, hardmask, a first spacer, and a gate spacer, in accordance with the embodiment of the present invention.

FIG. 4 illustrates a cross-section X of the nanosheet transistor after the formation and recessing of a lithography layer, in accordance with the embodiment of the present invention.

FIG. 5 illustrates a cross-section Y of the source/drain region after the formation and recessing of a lithography layer, in accordance with the embodiment of the present invention.

FIG. 6 illustrates a cross-section X of the nanosheet transistor after recessing of the gate spacers in the gate region, in accordance with the embodiment of the present invention.

FIG. 7 illustrates a cross-section X of the nanosheet transistor after the formation of a protective spacer and removal of the lithography layer, in accordance with the embodiment of the present invention.

FIG. 8 illustrates a cross-section Y of the source/drain region after the formation of a protective spacer and removal of the lithography layer, in accordance with the embodiment of the present invention.

FIG. 9 illustrates a cross-section X of the nanosheet transistor after the formation and patterning of a lithography layer, in accordance with the embodiment of the present invention.

FIG. 10 illustrates a cross-section Y of the source/drain region after the formation and patterning of a lithography layer, in accordance with the embodiment of the present invention.

FIG. 11 illustrates a cross-section Y of the source/drain region after removal of the exposed vertical segment of the gate spacer, in accordance with the embodiment of the present invention.

FIG. 12 illustrates a cross-section X of the nanosheet transistor after the formation of inner spacer and formation of source/drains, in accordance with the embodiment of the present invention.

FIG. 13 illustrates a cross-section Y of the source/drain region after the formation of inner spacer and formation of source/drains, in accordance with the embodiment of the present invention.

FIG. 14 illustrates a cross-section X of the nanosheet transistor after formation of the frontside interlayer dielectric layer, removal of the hardmask, dummy gate, and the sacrificial layers, and the formation of the gate, in accordance with the embodiment of the present invention.

FIG. 15 illustrates a cross-section Y of the source/drain region after formation of the frontside interlayer dielectric layer, removal of the hardmask, dummy gate, and the sacrificial layers, and the formation of the gate, in accordance with the embodiment of the present invention.

FIG. 16 illustrates a cross-section X of the nanosheet transistor after increasing the height of the frontside interlayer dielectric layer, formation of frontside contacts, frontside connection vias, an interconnect, and the carrier wafer, in accordance with the embodiment of the present invention.

FIG. 17 illustrates a cross-section Y of the source/drain region after increasing the height of the frontside interlayer dielectric layer, formation of frontside contacts, frontside connection vias, an interconnect, and the carrier wafer, in accordance with the embodiment of the present invention.

FIG. 18 illustrates a cross-section X of the nanosheet transistor after being flipped over for backside process, removal of the first substrate, the etch stop, and a portion of the second substrate, and the formation of a sacrificial cap, in accordance with the embodiment of the present invention.

FIG. 19 illustrates a cross section Y of the source/drain region after being flipped over for backside process, removal of the first substrate, the etch stop, and a portion of the second substrate, and the formation of a sacrificial cap, in accordance with the embodiment of the present invention.

FIG. 20 illustrates a cross-section X of the nanosheet transistor after formation and patterning of a lithography layer and formation of backside connection via trenches, in accordance with the embodiment of the present invention.

FIG. 21 illustrates a cross-section Y of the source/drain region after formation and patterning of a lithography layer and formation of backside connection via trenches, in accordance with the embodiment of the present invention.

FIG. 22 illustrates a cross-section Y of the source/drain region after a lateral etch process of the source/drain to create a protrusion of the backside connection via trench, in accordance with the embodiment of the present invention.

FIG. 23 illustrates a cross-section X of the nanosheet transistor after removal of the lithography layer and formation of the backside connection vias, in accordance with the embodiment of the present invention.

FIG. 24 illustrates a cross-section Y of the source/drain region after removal of the lithography layer and formation of the backside connection vias, in accordance with the embodiment of the present invention.

FIG. 25 illustrates a cross-section X of the nanosheet transistor after removal of the sacrificial cap and the second substrate, and formation of the backside interlayer dielectric layer, a plurality of metal lines, and a backside interconnect, in accordance with the embodiment of the present invention.

FIG. 36 illustrates a cross-section Y of the source/drain region after removal of the sacrificial cap and the second substrate, and formation of the backside interlayer dielectric layer, a plurality of metal lines, and a backside interconnect, in accordance with the embodiment of the present invention.

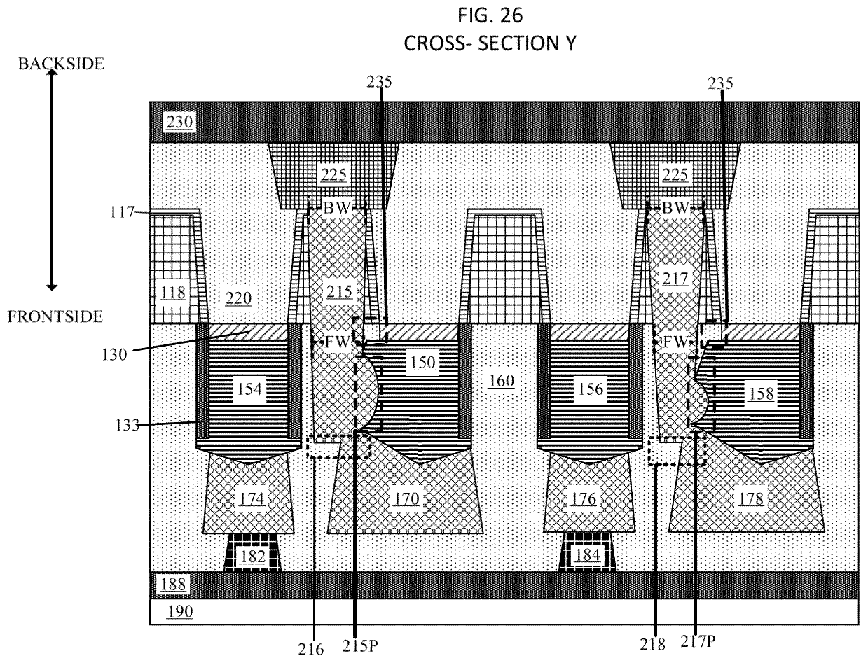

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards the formation of a wrap around source/drain contact, where the wrap around source/drain contact has a horizontal section located on the frontside of the source/drain and a connection via that extends towards the backside. The amount of available space to form the connection via is limited between adjacent source/drains. The limited amount of available space increases the difficulty of connecting the connection via with the horizontal section of the wrap around source/drain contact. To increase the limited amount of available space to form the connection via, prior to the formation of the source/drain, a confining gate vertical spacer (which is used to confine the growth of the source/drain) is removed. The removal of the confining gate vertical spacer allows for the lateral growth of the source/drain in the direction of where the confining gate vertical spacer was removed. The lateral growth of the source/drain extends into the area where the connection via is formed. The limited amount of space is increased because the lateral growth portion of the source/drain can be removed for the formation of the connection via, which has the benefit of increasing the available contact surface area between the source/drain and the connection via. The connection via removes a portion of the source/drain when making a connection with the horizontal section, but the surface area contact with the connection via is minimum. To increase the contact surface area between the source/drain and the connection via, a lateral etch process is utilized to etch/gouge laterally into the source/drain. A lateral hump/protrusion extends off the connection via into the source/drain to increase the contact surface area between the source/drain and the wrap around source/drain contact.

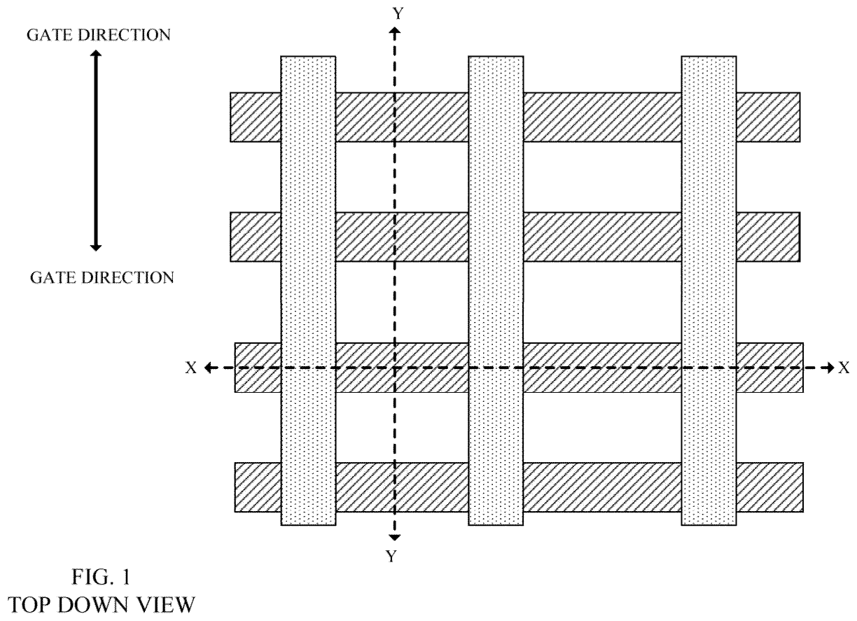

FIG. 1 illustrates a top-down view of multiple devices, in accordance with the embodiment of the present invention. The cross-section X extends horizontally through nanosheet transistors or field-effect-transistors. Cross section Y is perpendicular to cross section X, where cross section Y is through a source/drain region that spans across multiple adjacent nanosheet transistors or field-effect-transistors. Cross-section X is perpendicular to the gate direction and cross-section Y is parallel to the gate direction.

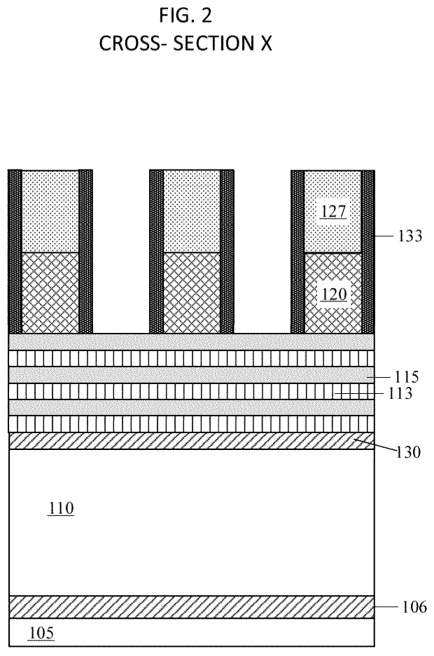

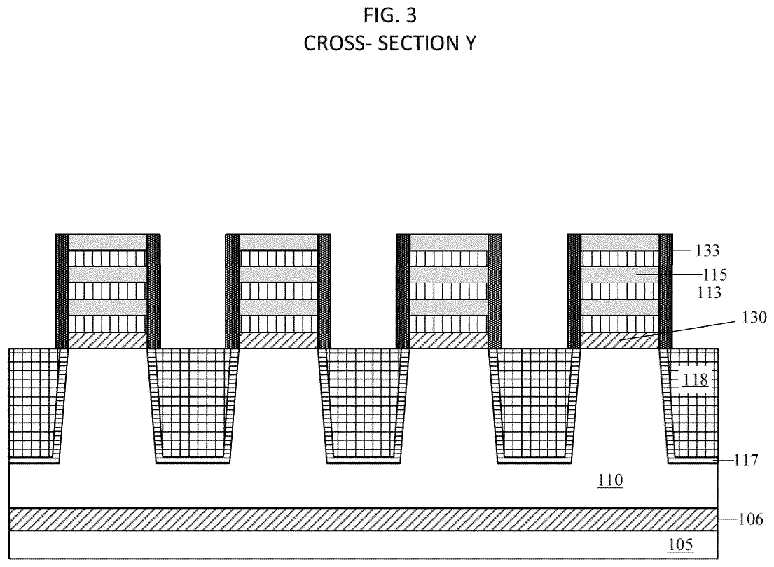

Referring now to FIGS. 2, and 3, a structure is shown during an intermediate step of a method of fabricating after the formation of the dummy gate 120, hardmask 127, a first spacer 130, and a gate spacer 133. FIG. 2 illustrates the nano stack of the nanosheet transistors that includes a first substrate 105, etch stop 106, second substrate 110, a plurality of layers, a first spacer 130, a dummy gate 120, and a hardmask 127, and gate spacer 133.

The plurality of layers includes alternating layers that includes channel layers 115 (e.g., nanosheets), and sacrificial layers 113. The plurality of channel layers 115 can be comprised of, for example, Si. The plurality of sacrificial layers 113 can be comprised of SiGe, where Ge is in the percentage of 15 to 35%.

The first substrate 105 and the second substrate 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of first substrate 105 and the second substrate 110. In some embodiments, first substrate 105 and the second substrate 110 includes both semiconductor materials and dielectric materials. The semiconductor first substrate 105 and the second substrate 110 may also comprise an organic semiconductor or a layered semiconductor such as, for example, Si/SiGe, a silicon-on-insulator or a SiGe-on-insulator. A portion or the entire semiconductor first substrate 105 and the second substrate 110 may also be comprised of an amorphous, polycrystalline, or monocrystalline. The semiconductor first substrate 105 and the second substrate 110 may be doped, undoped or contain doped regions and undoped regions therein.

FIG. 3 illustrates the source/drain region, where trenches (not shown) were formed in the second substrate 110 during a processing step to separate the alternating layers. These trenches (not shown) are filled with liner 117 and a shallow trench isolation layer 118. The retaining walls/structure to control the source/drain epitaxial growth includes the horizontal first spacer 130 t and a plurality of vertical gate spacer 133 segments. The first spacer 130 and the vertical segments of the gate spacer 133 will form the boundary/retaining walls for the formation of the source/drains which will be described in further detail below.

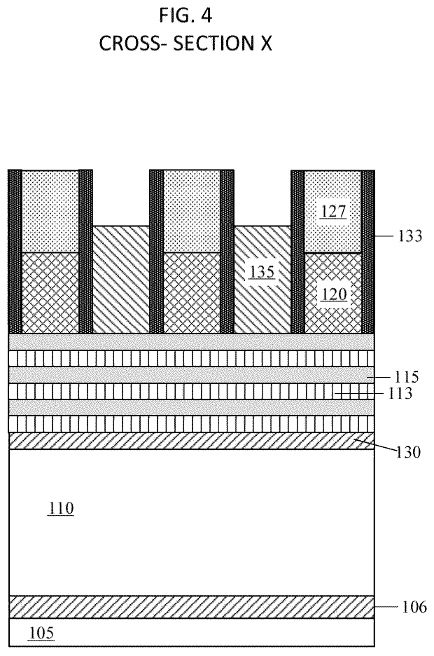

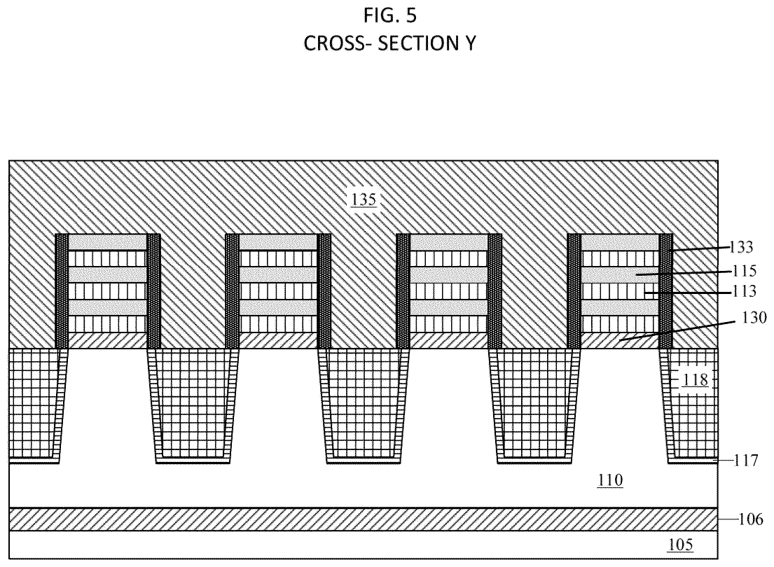

FIGS. 4 and 5 illustrate the processing stage after the formation and recessing of a lithography layer 135. A lithography layer 135 is formed on top of the nanosheet transistor device. Lithography layer 135 covers the source/drain region (as illustrated in FIG. 5) and covers the gate regions. The lithography layer 135 is recessed in the gate regions to expose a portion of the gate spacers 133, as illustrated in FIG. 4.

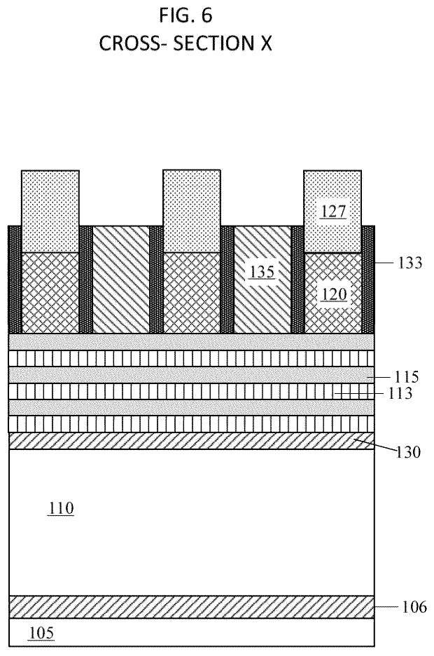

FIG. 6 illustrates the processing stage after recessing of the gate spacers 133 in the gate region. The exposed portions of the gate spacer 133 in the gate region are recessed/pulled down. The recessing/pulling down of the gate spacer 133 exposes the sidewall of hardmask 127.

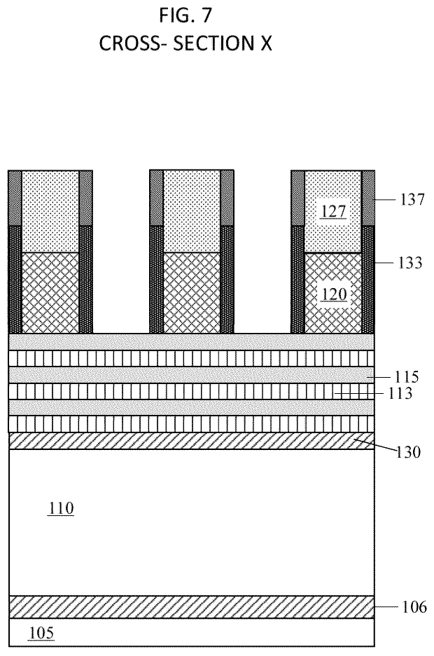

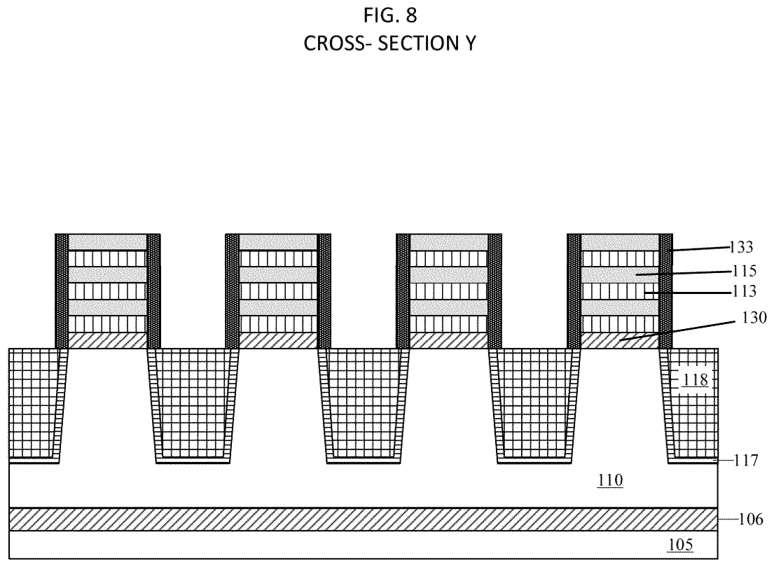

FIGS. 7 and 8 illustrate a processing stage after the formation of a protective spacer 137 and removal of the lithography layer 135. A protective spacer 137 is formed on top of gate spacer 133 in the gate region. The protective spacer 137 is located adjacent to hardmask 127 where the gate spacer 133 was removed. Lithography layer 135 is removed to expose the source/drain regions. The protective spacer 137 protects the gates spacer 133 located in the gate region during the removal of the vertical segments of the gate spacer 133 located in the source/drain region, which will be described in further detail below.

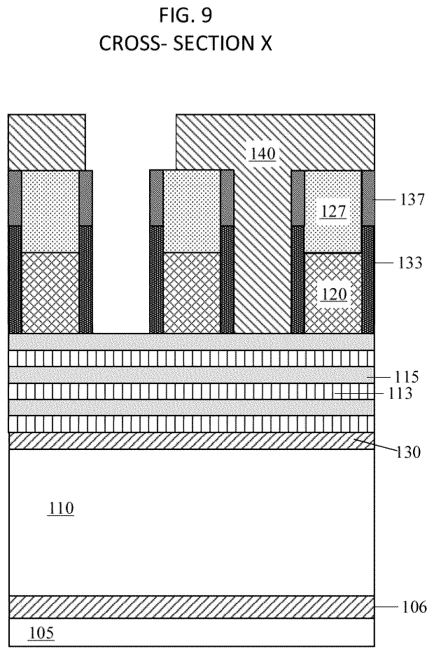

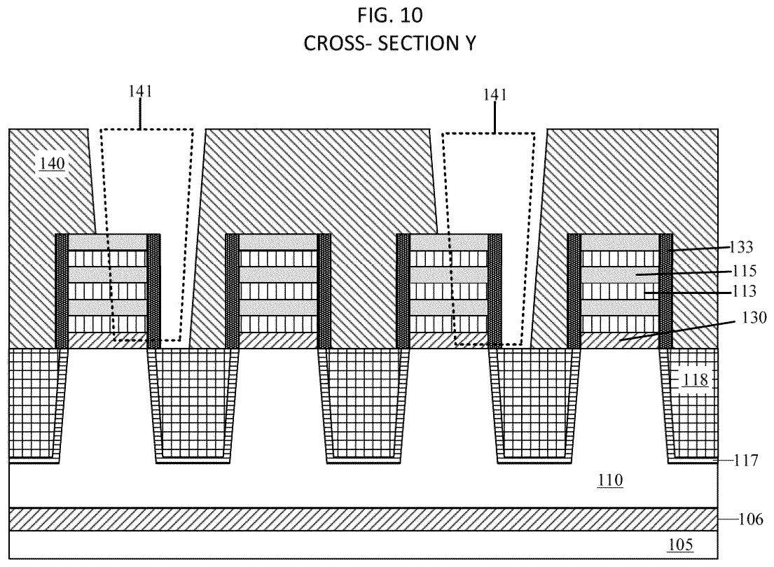

FIGS. 9 and 10 illustrate a processing stage after the formation and patterning of a lithography layer 140. Lithography layer 140 is formed on top of the gate regions and the source/drain regions of the nanosheet transistor device. Lithography layer 140 is patterned in different locations in the source/drain region to form a plurality of trenches 141. Each of the plurality of trenches 141 exposes one of the vertical segments of gate spacer 133 located in the source/drain region. The vertical segments of the gate spacer 133 in the source/drain region act as a boundary/retaining wall for the source/drain growth.

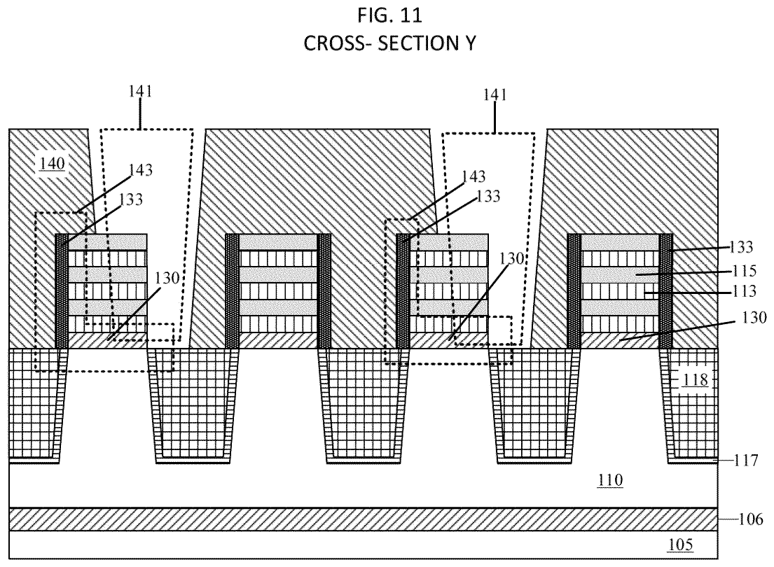

FIG. 11 illustrates the processing stage after removal of the exposed vertical segment of gate spacer 133 in the source/drain region. The vertical segments of gate spacer 133 exposed by trenches 141 in the source/drain region are removed. Protective spacer 137 protects/prevents the removal of the gate spacer 133 located in the gate region that were exposed by the plurality of trenches 141. The removal of the vertical segment of the gate spacer 133 removes one of the vertical retaining walls for the source/drain growth. Dash L-shape box 143 emphasizes the remaining vertical segment of the gate spacer 133 and the horizontal first spacer 130 that make up the remaining retaining walls for the source/drain growth. The lithography layer 140 prevents the removal of vertical segment of the gate spacer 133 for each of the source/drain locations. The vertical segments of gate spacer 133 located in the source/drain region that were exposed by trenches 141 are the only segments of the gate spacer 133 that were removed.

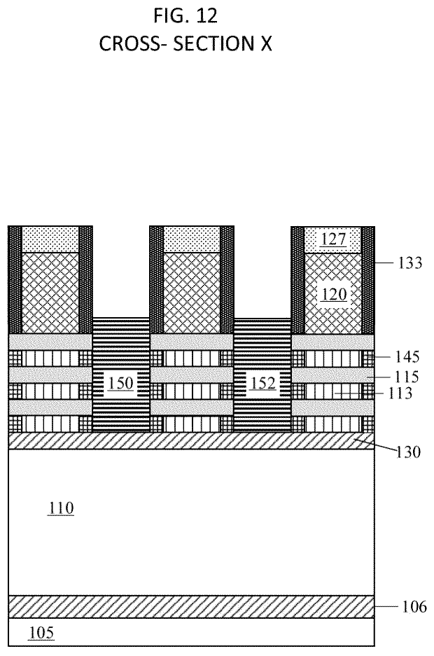

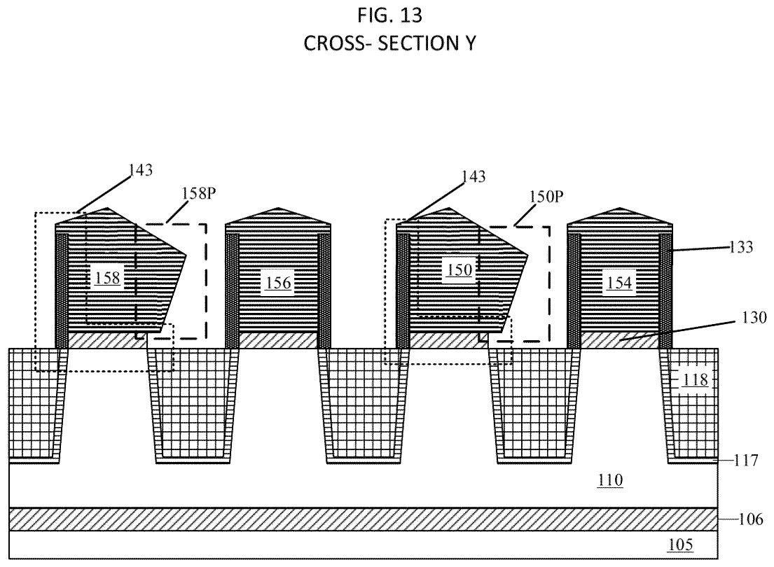

FIGS. 12 and 13 illustrate the stage after the formation of inner spacer 145 and formation of source/drains 150, 152, 154, 156, 158. Lithography layer 140 is removed and sacrificial layers 113 are recessed. The alternating layers (e.g., the channel layers 115 and sacrificial layers 113) are removed from the source/drain region. Inner spacer 145 is formed in the locations where the sacrificial layer 113 was recessed. Source/drains 150, 152, 154, 156, 158 are epitaxially grown in the source/drain region. For example, the source/drains 154, 156 are grown with at least two vertical segments of the gate spacer 133 that act as a retaining wall for the growth of the source/drains 154, 156. The two vertical segments of gate spacer 133 prevent the lateral growth of the source/drains 154, 156. Source/drains 150, 158 are missing one of the vertical segments of the gate spacer 133, thus the source/drains 150, 158 laterally grew in the direction of the missing vertical segment gate spacer 133. The lateral growth of the source/drain 150, 158 caused the source/drains 150, 158 to develop a protrusion (for example, dashed boxes 150P, 158P, respectively) that extends towards an adjacent source/drain 154, 156. The protrusions 150P, 158P extends over the shallow trench isolation layer 118.

The source/drains 150, 152, 154, 156, 158 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

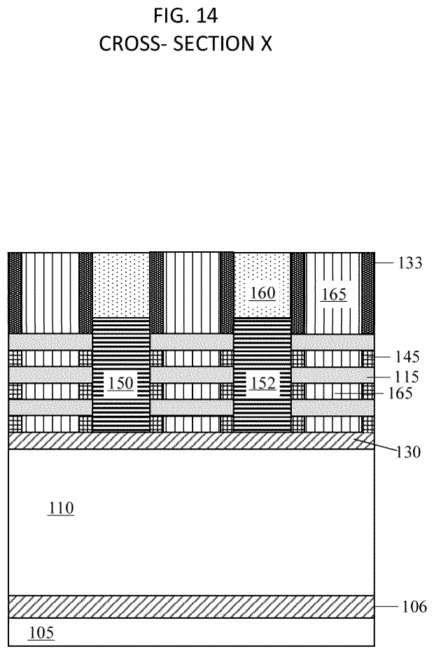

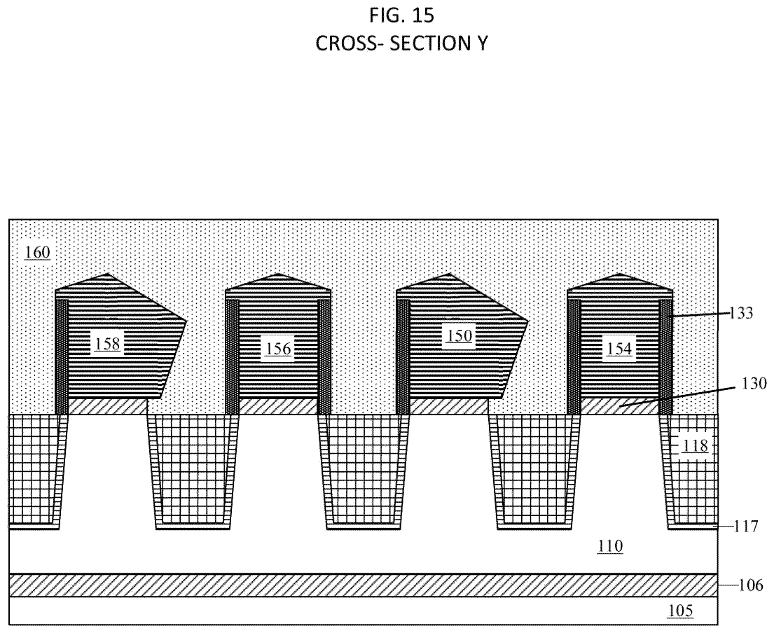

FIGS. 14 and 15 illustrate the processing stage after formation of the frontside interlayer dielectric layer 160, removal of the hardmask 127, dummy gate 120, and the sacrificial layers 113, and the formation of the gate 165. Frontside interlayer dielectric layer 160 is formed on top of the source/drains 150, 152, 154, 156, 158. The hardmask 127, dummy gate 120, and the sacrificial layers 113 are removed to create space for the formation of gate 165. Gate 165 is formed in the empty space created by the removal of these layers. Gate 165 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

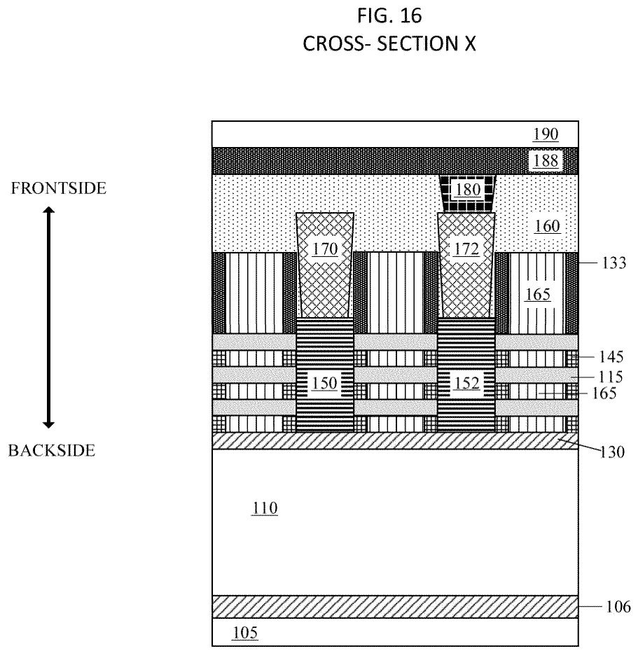

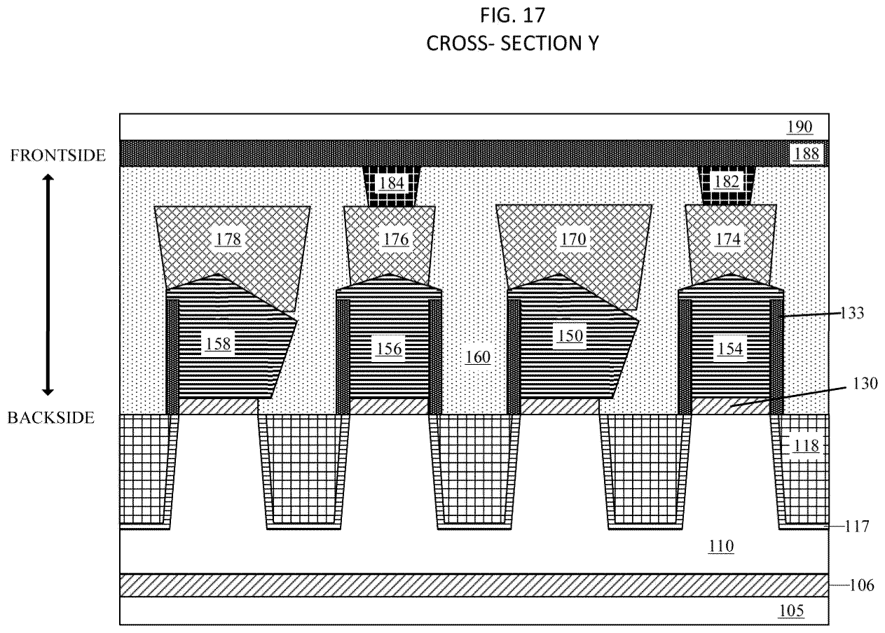

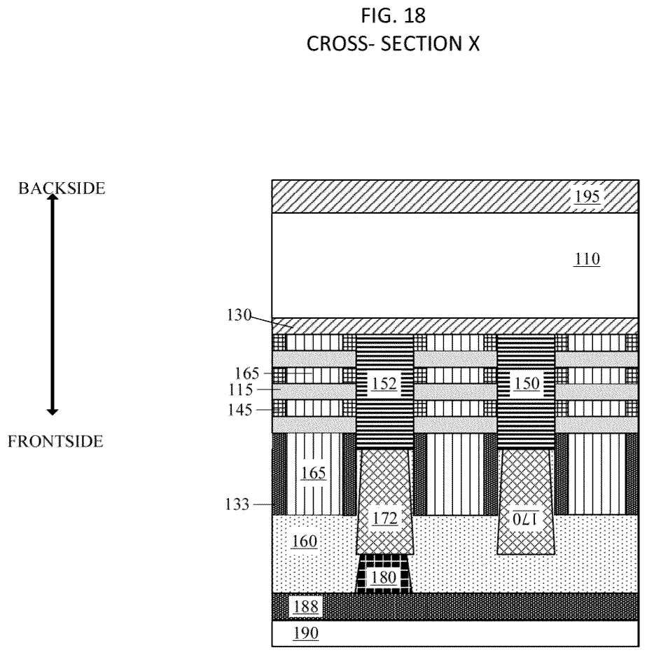

FIGS. 16 and 17 illustrate the processing stage after increasing the height of the frontside interlayer dielectric layer 160, formation of frontside contacts 170, 172, 174, 176, 178, frontside connection vias 180, 182, 184, an interconnect 188, and the carrier wafer 190. The height of the frontside interlayer dielectric layer 160 is increased, so that the frontside interlayer dielectric layer 160 extends over the top of the gates 165. A plurality of trenches (not shown) is formed in the source/drain region and the gate region, where each of the trenches exposes a top surface of one of the source/drains 150, 152, 154, 156, 158, or a top surface of gate 165, respectively. A metallization process fills these trenches (not shown) with a conductive metal to form the frontside contacts 170, 172, 174, 176, 178, and gate contacts (not shown). The height of the frontside interlayer dielectric layer 160 is increased to extend on top of the frontside contacts 170, 172, 174, 176, 178, and gate contacts (not shown). A plurality of trenches (not shown) are formed in the frontside interlayer dielectric layer 160 located over frontside contacts 172, 174, 176 that are connected to a source/drains 152, 154, 156 that do not have a protrusion, and a trench (not shown) are formed in the frontside interlayer dielectric layer 160 over gate contact (not shown). A metallization process fills these trenches (not shown) with a conductive metal to form the connection vias 180, 182, 184, and a gate connection via (not shown). Each of the connection vias 180, 182, 184 are connected to separate frontside contacts 172, 174, 176, respectively. An interconnect 188, for example, a back-end-of-the-line (BEOL) layer, is formed on top of the frontside interlayer dielectric layer 160 and on top of the connection vias 180, 182, 184, and gate connection via (not shown). The interconnect 188 can be comprised of multiple layers, metal lines, vias, skip vias, or other components, or any combination thereof. Carrier wafer 190 is formed on top of interconnect 188. The carrier wafer 190 allows for nanosheet device (i.e., the chip) to be flipped over for backside processing. FIGS. 2-17 illustrated the frontside processing of the nanosheet device while FIG. 18-26 illustrate the backside processing of the nanosheet device.

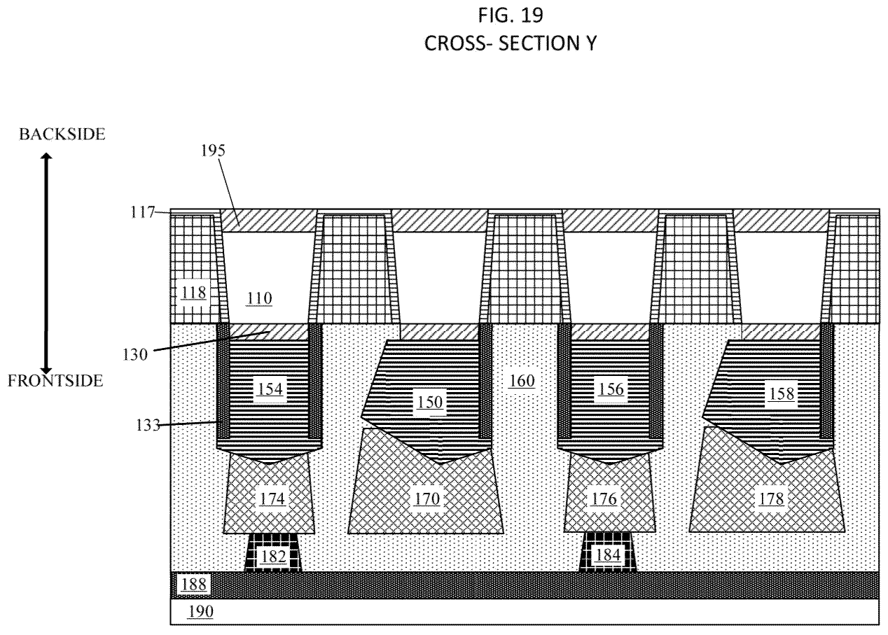

FIGS. 18 and 19 illustrate the processing stage after the nanosheet device has been flipped over for backside processing, removal of the first substrate 105, the etch stop 106, and a portion of the second substrate 110, and the formation of a sacrificial cap 195. The nanosheet device (i.e., the chip/wafer) is flipped over to allow for backside processing. The first substrate 105 and the etch stop 106 are removed. A portion of the second substrate 110 is removed and a sacrificial cap 195 is formed on top of the second substrate 110.

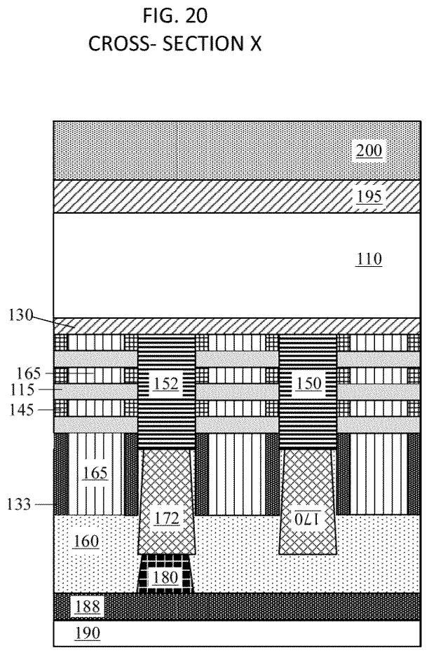

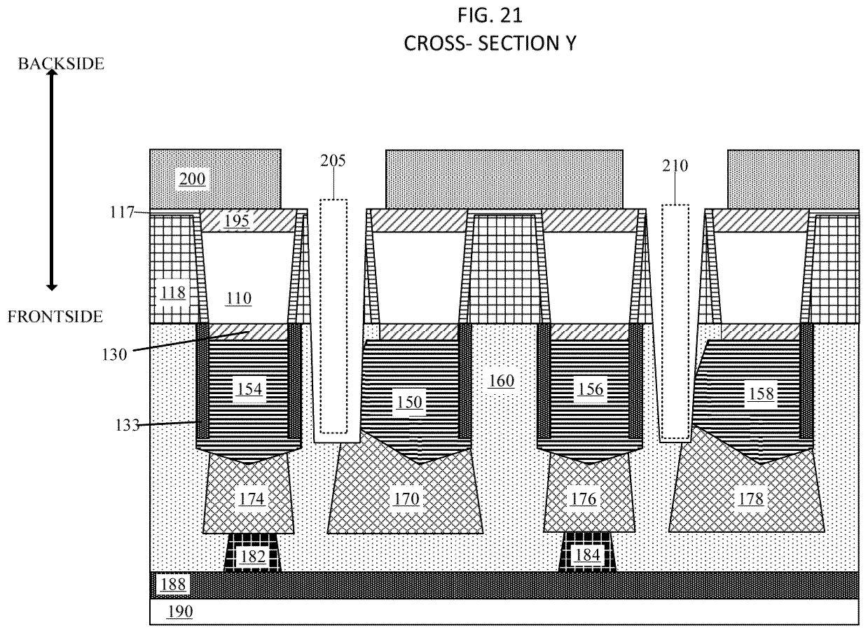

FIGS. 20 and 21 illustrate the processing stage after formation and patterning of a lithography layer 200 and formation of backside connection via trenches 205, 210. A lithography layer 200 is formed on top of the liner 117 and the sacrificial cap 195. The lithography layer 200 is patterned, where the pattern exposes the liner 117. Liner 117, shallow trench isolation layer 118, the frontside interlayer dielectric layer 160, and portions of the protrusions 150P, 158P of source/drains 150, 158 are etched to form the backside connection via trenches 205, 210. The backside connection via trenches 205, 210 extend downwards (i.e., towards the frontside) into the frontside contacts 170, 178, respectively. Backside connection via trench 210 illustrates an ideal alignment where only a small portion of the protrusion 158P of the source/drain 158 is removed. Backside connection via trench 205 illustrates a situation where the trench is not in an ideal alignment. In the illustrated example, the misalignment causes more of the protrusion 150P of the source/drain 150 to be removed than the amount of the protrusion 158P to be removed from source/drain 158. The backside connection via trenches 205, 210 interaction of the protrusion 150P, 158, determines how much of the sidewall of the source/drains 150, 158 is exposed. The exposed side surfaces of the source/drains 150, 158 will allow for an increase contact surface area between the source/drains 150, 158 and the backside connection via, which will be described in further detail below. The bottom surface/bottom wall of the backside connection via trenches 205, 210 is formed by the frontside interlayer dielectric layer 160 and the frontside contacts 170, 178, respectively. Only a portion of the bottom wall of the backside connection via trenches 205, 210 is formed by the frontside contacts.

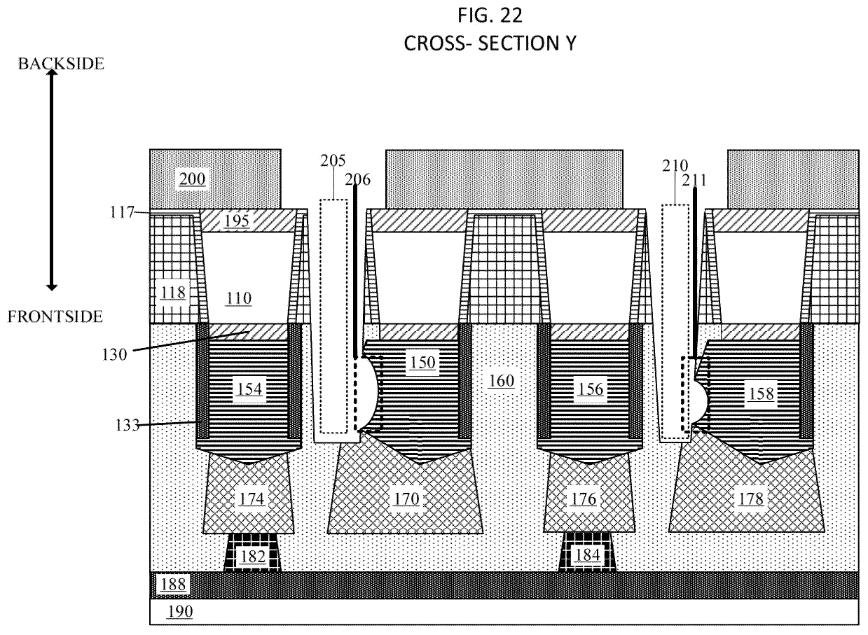

FIG. 22 illustrates the processing stage after a lateral etch process of the source/drain 150, 158, to create a protrusion of the backside connection via trench 205, 210. A lateral etch process, or a lateral gouging process laterally etches/gouges the protrusions 150P, 158P of the source/drain 150, 158. The lateral gouged area/lateral trench extensions 206, 211 extend from where the backside connection via trench 205, 210 exposed a portion of the sidewall (i.e., a portion of the protrusions 150P, 158P) of the source/drain 150, 158 into the source/drains 150, 158, respectively. A gouge/void/trench extension 206, 211 is formed in the source/drains 150, 158 from the lateral etch process where the gouge/void area is connected to the backside connection via trenches 205, 210. The size of the gouge/void/trench extension 206, 211 is affected by the alignment of the backside connection via trench 205, 210. The backside connection via trench 205 exposed a larger sidewall of source/drain 150 than the sidewall of source/drain 158 exposed backside connection via trench 210 (see, for example, FIG. 21). The exposed vertical height of sidewall of source/drain 150, 158 affects the vertical height of the formed gouge/void/trench extension 206, 211 that is formed. The gouge/void/trench extension 206, 211 increases the amount of surface area of the source/drain 150, 158 that is exposed, respectively.

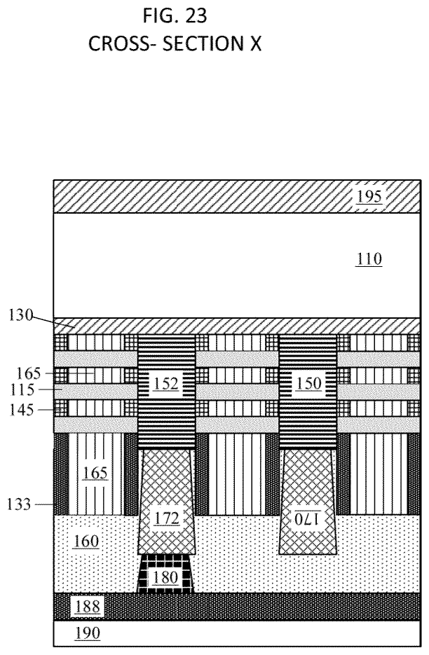

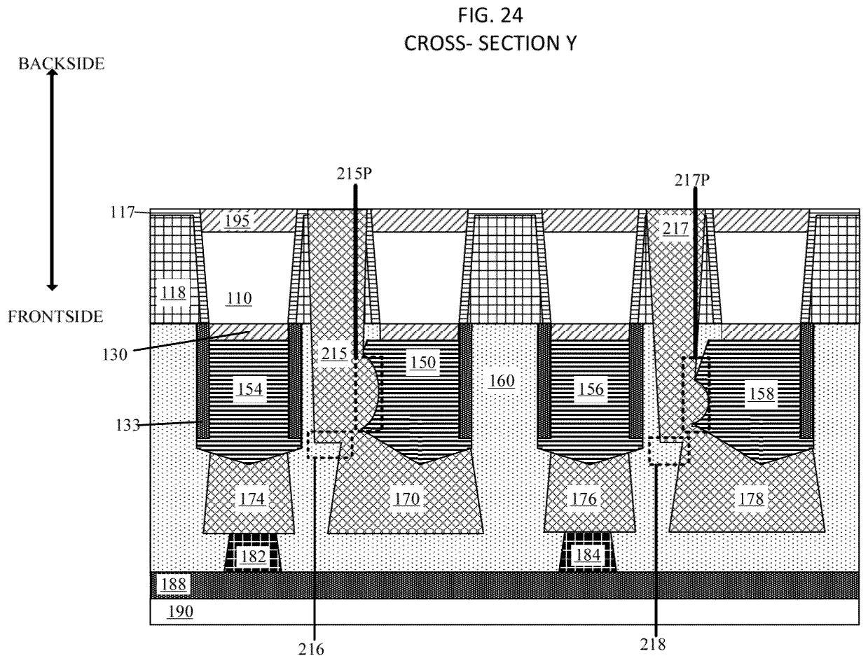

FIGS. 23 and 24 illustrate the processing stage after removal of the lithography layer 200 and formation of the backside connection vias 215, 217. Lithography layer 200 is removed and a metallization process fills the backside connection via trenches 205, 210 with a conductive metal. Backside connection vias 215, 217 are formed from the backside connection via trenches 205, 210 and the backside connection vias 215, 217 are in contact with frontside contacts 170, 178, respectively. Backside connection vias 215, 217 have protrusion 215P, 217P that extends into the source/drains 150, 158, respectively. Source/drains 150, 158 wrap around the protrusion 215P, 217P, as illustrated in FIG. 24. The protrusion 215P, 217P increases the surface contact area between the source/drains 150, 158 and the wrap around contact (which is comprised of the frontside contact 170, 178, the backside connection via 215, 217, and the protrusions 215P, 217P). Dash boxes 216, 218 emphasize an area of the backside connection via 215, 217 that forms a horizontal surface that extends from the area where the frontside contact 170, 178 and the backside connection vias 215, 217 are connected to each other. The backside connection via 215, 217 have a bottom surface (or frontside surface) that is in contact with the frontside interlayer dielectric layer 160, as emphasized by dashed boxes 216, 218.

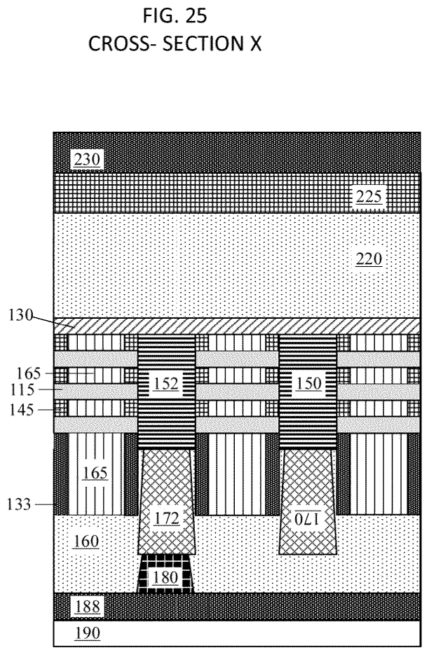

FIGS. 25 and 26 illustrate the processing stage after removal of the sacrificial cap 195 and the second substrate 110, and formation of the backside interlayer dielectric layer 220, a plurality of metal lines 225, and a backside interconnect 230. The sacrificial cap 195 and the second substrate 110 are removed which exposes a backside surface of the first spacer 130. A backside interlayer dielectric layer 220 is formed in the space of the removed layers (e.g., the sacrificial cap 195, and the second substrate 110) and the backside interlayer dielectric layer 220 extends on top of the backside connection vias 215, 217. Trenches (not shown) are formed in backside interlayer dielectric layer 220, where the backside surface of the backside connection vias 215, 217 are exposed by one of the trenches (not shown). A feature of the source/drains 150, 158 where the lateral growth is shown is because the source/drain 150, 158 extends past the end of the first spacer 130, as emphasized by dashed box 235. Since the connection vias 215, 217 are formed from the backside of the device then the connection vias 215, 217 have a backside width BW and a frontside width FW. The frontside width FW is located close to the source/drains 150, 158 and the backside width BW is located at a backside surface of the via section 215, 217 of the wrap around contact 170, 215, 178, 217. The backside width BW is larger than the frontside width FW

A plurality of metal lines 225 are formed by filling these trenches (not shown) with a conductive metal. The plurality of metal lines 225 can be, for example, a VSS power rail, a VDD power rail, a signal line, a ground line, another type of metal line, or any combination thereof. A backside interconnect 230 is formed on top of the backside interlayer dielectric layer 220, and on top of the plurality of metal lines 225. The backside interconnect 230 can be any type of interconnect that is comprised of one or more layers, one or more metal lines, one or more vias, or any other type of interconnect. For example, the backside interconnect 230 can be a backside-power-distribution-network (BSPDN).

A microelectronic structure includes a nanosheet FET that includes a source/drain 150, 158. A wrap around contact 170, 215, 178, 217 that is connected to the source/drain 150, 158. The wrap around contact 170, 215, 178, 217 includes a horizontal section 170, 178 and a via section 215, 217. The via section 215, 217 includes a protrusion 215P, 217P that extends laterally into the source/drain 150, 158.

The horizontal section 170, 178 of the wrap around contact 170, 215, 178, 217 is located on a frontside surface of the source/drain 150, 158. The via section 215, 217 of the wrap around contact 170, 215, 178, 217 has a backside width BW and a frontside width FW. The frontside width FW is located close to the source/drain 150, 158 and the backside width BW is located at a backside surface of the via section 215, 217 of the wrap around contact 170, 215, 178, 217. The backside width BW is larger than the frontside width FW. The source/drain 150, 158 separates the protrusion 215P, 217P of the via section 215, 217 and the horizontal section 170, 178 of the wrap around contact 170, 215, 178, 217.

A buried metal line 225 located on a backside surface of the via section 215, 217 of the wrap around contact 170, 215, 178, 217.

An interlayer dielectric layer 160 located around the horizontal section 170, 178 of the wrap around contact 170, 215, 178, 217 and around a portion of the via 215, 217 section of the wrap around contact 170, 215, 178, 217.

A frontside 216, 218 of the via section 215, 217 of the wrap around contact 170, 215, 178, 217 is connected to a backside of the horizontal section 170, 178 of the wrap around contact 170, 215, 178, 217. The via section 215, 217 of the wrap around contact 170, 215, 178, 217 has a frontside surface 216, 218 that is in contact with the interlayer dielectric layer 160. The frontside surface 216, 218 of the via section 215, 217 is adjacent to where the via section 215, 217 is connected to the horizontal section 170, 178 of the wrap around contact 170, 215, 178, 217.

A microelectronic structure a nanosheet FET that includes a source/drain 150. A horizontal spacer 130 located on a backside surface of the source/drain 150, 158. The source/drain 150, 158 extends past the end of the sidewall of the horizontal spacer 130 (as emphasized by dashed box 235). A vertical spacer 133 located along a sidewall of the source/drain 150, 158. A wrap around contact 170, 215, 178, 217 that is connected to the source/drain 150, 158. The wrap around contact 170, 215, 178, 217 includes a horizontal section 170, 178 and a via section 215, 217. The via section 215, 217 includes a protrusion 215P, 217P that extends laterally into the source/drain 150, 158.

The horizontal section 170, 178 of the wrap around contact 170, 215, 178, 217 is located on a frontside surface of the source/drain 150, 158.

The via section 215, 217 of the wrap around contact 170, 215, 178, 217 has a backside width BW and a frontside width FW. The frontside width FW is located close to the source/drain 150, 158 and the backside width BW is located at a backside surface of the via section 215, 217 of the wrap around contact 170, 215, 178, 217. The backside width BW is larger than the frontside width FW.

The vertical spacer 133 is located on a opposite side of the source/drain 150, 158 as the via section 215, 217 of the wrap around contact 170, 215, 178, 217.

The source/drain 150, 158 separates the protrusion 215P, 217P of the via section 215, 217 and the horizontal section 170, 178 of the wrap around contact 170, 215, 178, 217.

A buried metal line 225 located on a backside surface of the via section 215, 217 of the wrap around contact 170, 215, 178, 217.

An interlayer dielectric layer 160 located around the horizontal section 170, 178 of the wrap around contact 170, 215, 178, 217 and around a portion of the via section 215, 217 of the wrap around contact 170, 215, 178, 217.

A frontside 216, 218 of the via section 215, 217 of the wrap around contact 170, 215, 178, 217 is connected to a backside of the horizontal section 170, 178 of the wrap around contact 170, 215, 178, 217.

The via section 215, 217 of the wrap around contact 170, 215, 178, 217 has a frontside surface 216, 218 that is in contact with the interlayer dielectric layer 160. The frontside surface 216, 218 of the via section 215, 217 is adjacent to where the via section 215, 217 is connected to the horizontal section 170, 178 of the wrap around contact 170, 215, 178, 217.

A microelectronic structure a nanosheet FET that includes a source/drain 150. A horizontal spacer 130 located on a backside surface of the source/drain 150, 158. The source/drain 150, 158 extends past the end of the sidewall of the horizontal spacer 130 (as emphasized by dashed box 235). A vertical spacer 133 located along a sidewall of the source/drain 150, 158. A first side of the source/drain 158 is in direct with the vertical spacer 133. A wrap around contact 170, 215, 178, 217 that is connected to the source/drain 150, 158. The wrap around contact 170, 215, 178, 217 includes a horizontal section 170, 178 and a via section 215, 217. The via section 215, 217 includes a protrusion 215P, 217P that extends laterally into the source/drain 150, 158.

The horizontal section 170, 178 of the wrap around contact 170, 215, 178, 217 is located on a frontside surface of the source/drain 150, 158. The via section 215, 217 of the wrap around contact 170, 215, 178, 217 is in contact with a second side of the source/drain 150, 158. The first side of the source/drain 150, 158 and the second side of the source/drain 150, 158 are located on opposite sides of the source/drain 150, 158 (as illustrated, for example, in FIG. 26).

The source/drain 150, 158 separates the protrusion 215P, 217P of the via section 215, 217 and the horizontal section 170, 178 of the wrap around contact 170, 215, 178, 217.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet FET that includes a source/drain; and
a wrap around contact that is connected to the source/drain, wherein the wrap around contact includes a horizontal section and a via section, wherein the via section includes a protrusion that extends laterally into the source/drain.

2. The microelectronic structure of claim 1, wherein the horizontal section of the wrap around contact is located on a frontside surface of the source/drain.

3. The microelectronic structure of claim 2, wherein the via section of the wrap around contact has a backside width and a frontside width, wherein the frontside width is located close to the source/drain and the backside width is located at a backside surface of the via section of the wrap around contact, wherein the backside width is larger than the frontside width.

4. The microelectronic structure of claim 1, wherein the source/drain separates the protrusion of the via section and the horizontal section of the wrap around contact.

5. The microelectronic structure of claim 4, further comprising:
a buried metal line located on a backside surface of the via section of the wrap around contact.

6. The microelectronic structure of claim 1, further comprising:
an interlayer dielectric layer located around the horizontal section of the wrap around contact and around a portion of the via section of the wrap around contact.

7. The microelectronic structure of claim 6, wherein a frontside of the via section of the wrap around contact is connected to a backside of the horizontal section of the wrap around contact.

8. The microelectronic structure of claim 7, wherein the via section of the wrap around contact has a frontside surface that is in contact with the interlayer dielectric layer, wherein the frontside surface of the via section is adjacent to where the via section is connected to the horizontal section of the wrap around contact.

9. A microelectronic structure comprising:
a nanosheet FET that includes a source/drain;
a horizontal spacer located on a backside surface of the source/drain, wherein the source/drain extends past the end of the sidewall of the horizontal spacer;
a vertical spacer located along a sidewall of the source/drain; and
a wrap around contact that is connected to the source/drain, wherein the wrap around contact includes a horizontal section and a via section, wherein the via section includes a protrusion that extends laterally into the source/drain.

10. The microelectronic structure of claim 9, wherein the horizontal section of the wrap around contact is located on a frontside surface of the source/drain.

11. The microelectronic structure of claim 10, wherein the via section of the wrap around contact has a backside width and a frontside width, wherein the frontside width is located close to the source/drain and the backside width is located at a backside surface of the via section of the wrap around contact, wherein the backside width is larger than the frontside width.

12. The microelectronic structure of claim 11, wherein the vertical spacer is located on a opposite side of the source/drain as the via section of the wrap around contact.

13. The microelectronic structure of claim 9, wherein the source/drain separates the protrusion of the via section and the horizontal section of the wrap around contact.

14. The microelectronic structure of claim 13, further comprising:
a buried metal line located on a backside surface of the via section of the wrap around contact.

15. The microelectronic structure of claim 9, further comprising:
an interlayer dielectric layer located around the horizontal section of the wrap around contact and around a portion of the via section of the wrap around contact.

16. The microelectronic structure of claim 15, wherein a frontside of the via section of the wrap around contact is connected to a backside of the horizontal section of the wrap around contact.

17. The microelectronic structure of claim 16, wherein the via section of the wrap around contact has a frontside surface that is in contact with the interlayer dielectric layer, wherein the frontside surface of the via section is adjacent to where the via section is connected to the horizontal section of the wrap around contact.

18. A microelectronic structure comprising:
a nanosheet FET that includes a source/drain;
a horizontal spacer located on a backside surface of the source/drain, wherein the source/drain extends past the end of the sidewall of the horizontal spacer;
a vertical spacer located along a sidewall of the source/drain, wherein a first side of the source/drain is in direct with the vertical spacer; and
a wrap around contact that is connected to the source/drain, wherein the wrap around contact includes a horizontal section and a via section, wherein the via section includes a protrusion that extends laterally into the source/drain.

19. The microelectronic structure of claim 18, wherein the horizontal section of the wrap around contact is located on a frontside surface of the source/drain, wherein the via section of the wrap around contact is in contact with a second side of the source/drain, and wherein the first side of the source/drain and the second side of the source/drain are located on opposite sides of the source/drain.

20. The microelectronic structure of claim 18, wherein the source/drain separates the protrusion of the via section and the horizontal section of the wrap around contact.
